(19) United States
(12) Patent Application Publication
(10) Pub. No.: US 2007/0300112 A1
(43) Pub. Date: Dec. 27, 2007

(54) SEMICONDUCTOR INTEGRATED CIRCUIT APPARATUS, TEST CIRCUIT OF SEMICONDUCTOR INTEGRATED CIRCUIT APPARATUS AND TEST METHOD OF SEMICONDUCTOR INTEGRATED CIRCUIT APPARATUS

(75) Inventor: Takashi Matsumoto, Chiba (JP)

Correspondence Address: AMIN, TUROCY & CALVIN, LLP, 1900 EAST 9TH STREET, NATIONAL CITY CENTER, 24TH FLOOR,, CLEVELAND, OH, 44114, US

(73) Assignee: KABUSHIKI KAISHA TOSHIBA, Tokyo (JP)

(21) Appl. No.: 11/755,875

(22) Filed: May 31, 2007

(30) Foreign Application Priority Data
Jun. 7, 2006 (JP) 2006-158892

(51) Int. Cl. G01R 31/28

(52) U.S. Cl. 714/731

(57) ABSTRACT

A semiconductor integrated circuit apparatus includes: a plurality of flip-flops configured to operate with clocks having mutually different frequencies; an oscillator configured to output oscillation output that is a source of the clocks supplied to the flip-flops; a storage part configured to store control data for a delay fault test; a pulse control part configured to use the oscillation output of the oscillator to generate a launch clock and a capture clock used in the delay fault test, based on the control data, the pulse control part generating the launch clock and the capture clock having pulse widths corresponding to periods of the clocks which operate the flip-flops.

### CROSS-REFERENCE TO RELATED APPLICATIONS

This application is based upon and claims the benefit of priority from the prior Japanese Patent Application No. 2006-158892 filed on Jun. 7, 2006; the entire contents of which are incorporated herein by reference.

### BACKGROUND OF THE INVENTION

1. Field of the Invention

The present invention relates to a semiconductor integrated circuit apparatus for which a delay fault test can be performed, a test circuit of the semiconductor integrated circuit apparatus, and a test method of the semiconductor integrated circuit apparatus.

2. Description of the Related Art

Conventionally, in a large-scale integrated circuit (LSI) which includes sequential circuits, a large number of flip-flop circuits are configured. For the purpose of fault diagnosis of such a LSI, a scan test may be employed. The scan test is adapted to determine whether a fault is present or not, by configuring the flip-flops in the circuit as scan flip-flops with chained paths and observing input/output.

As semiconductor integrated circuits for which such a scan test can be performed, various circuits are proposed such as circuits described in Japanese Patent Laid-Open No. 2004-354059 and Japanese Patent Laid-Open No. 8-201481.

Further, in recent years, with speedup of the interest circuits, a test for delay fault (a delay fault test) has been also employed. The delay fault test is adapted to determine whether data can be changed within a predetermined delay time or not, for combinational circuit parts between flip-flops of a scan-designed circuit.

In the delay fault test, at first, a scan chain is utilized to set required values for the flip-flops. Next, two clock signals are applied with frequencies desired for the test, at high speed. Thereby, change in the value generated in a former flip-flop in the first clock is captured into a latter flip-flop in the second clock. By observing output of the flip-flops, delay fault in the test frequency between the former flip-flop and the latter flip-flop can be detected.

Furthermore, in recent years, drive frequencies of elements in the LSI have been extremely high and a high speed clock having a frequency of 500 MHz may be used, for example. In this case, the flip-flops are required to operate at high speed within 2 ns and accordingly a test using a high speed clock is required in the delay fault test in order to support such a high speed operation. In this case, if it is attempted to supply the clock for the test from a tester outside of the LSI, measurement of the delay fault test is difficult due to wave form distortion. Thus, it is contemplated to generate the test clock by using output of a PLL circuit configured in the LSI. In other words, the test clock is generated by selecting an output clock of the PLL circuit with a timing corresponding on a test pattern.

Moreover, in the LSI, elements driving at high speed and elements driving at low speed are provided in a mixed manner. In this case, the test pattern represents a timing corresponding to a short period for the elements driving at high speed and a timing corresponding to a long period for the elements driving at low speed. By selecting the output clock of the PLL circuit with a timing corresponding on the test pattern, the test clock for the delay fault test of the element, in which the elements driving at high speed and the elements driving at low speed are provided in a mixed manner, can be generated.

However, because such a test clock is generated by selecting the output of the PLL circuit in accordance with the test pattern, both test clocks supplied to elements driving at high speed and elements driving at low speed have a fixed pulse width in accordance with the output of the PLL circuit.

Therefore, sufficient accuracy for test results of the delay fault test may not be obtained. For example, in a circuit in which elements operating at rise edges and elements operating at fall edges are provided in a mixed manner, if a test clock having a shorter pulse width than that of the clock in the normal operation is provided, under the assumption that a signal path from the elements operating at rise edges to the elements operating at fall edges is present, the elements are operated with a shorter period than the original timing constraint of the signal path, which can result in generation of mismatch of expected values.

Further, if a rise transition time and a fall transition time of a clock line are asymmetrical, the smallest pulse width may not be satisfied or disappearance of the test clock may cause in the test clock having a shorter pulse width than the original pulse width.

### BRIEF SUMMARY OF THE INVENTION

A semiconductor integrated circuit apparatus according to one aspect of the present invention includes: a plurality of flip-flops configured to operate with clocks having mutually different frequencies; an oscillator configured to output oscillation output that is a source of the clocks supplied to the flip-flops; a storage part configured to store control data for a delay fault test; a pulse control part configured to use the oscillation output of the oscillator to generate a launch clock and a capture clock used in the delay fault test, based on the control data, the pulse control part generating the launch clock and the capture clock having pulse widths corresponding to periods of the clocks which operate the flip-flops.

### BRIEF DESCRIPTION OF THE DRAWINGS

FIG. 1 is a block view showing a semiconductor integrated circuit apparatus according to a first embodiment of the present invention;

FIG. 2 is a block view illustrating elements configured on the semiconductor integrated circuit apparatus in FIG. 1;

FIGS. 3A to 3C are timing charts showing clock signals A to C which are used in a FF group A 21 to a FF group C 23 in FIG. 2;

FIGS. 4A to 4C are timing charts illustrating timing constraints of signal paths;

FIGS. 5A to 5C are timing charts illustrating timing constraints of signal paths;

FIGS. 6A to 6C are timing charts illustrating timing constraints of signal paths;

FIG. 7 is a block view showing a concrete configuration of a cycle control part 12 in FIG. 1;

FIG. 8 is a state transition diagram illustrating output states of a control signal generating circuit 32 which is configured by a state machine;

FIG. 9 is a state transition diagram showing a concrete configuration of a substate ST01;

FIG. 10 is a state transition diagram showing a concrete configuration of a substate ST02; ST03;

FIGS. 12A to 12H are timing charts illustrating operation of the first embodiment;

FIGS. 13A to 13H are timing charts illustrating operation of the first embodiment;

FIGS. 14A to 14H are timing charts illustrating operation of the first embodiment;

FIGS. 15A to 15H are timing charts illustrating operation of the first embodiment;

FIGS. 16A to 16H are timing charts illustrating operation of the first embodiment;

FIGS. 17A to 17H are timing charts illustrating operation of the first embodiment;

FIGS. 18A to 18H are timing charts illustrating operation of the first embodiment;

FIGS. 19A to 19H are timing charts illustrating operation of the first embodiment;

FIGS. 20A to 20H are timing charts illustrating operation of the first embodiment;

FIG. 21 is a block view showing a configuration of the cycle control part which is employed in a second embodiment of the present invention;

FIG. 22 is an illustrative view showing contents of a table in a pattern conversion table 42;

FIG. 23 is an illustrative view showing contents of a table in the pattern conversion table 42;

FIG. 24 is an illustrative view showing contents of a table in the pattern conversion table 42;

FIG. 25 is an illustrative view showing contents of a table in the pattern conversion table 42;

FIG. 26 is an illustrative view showing contents of a table in the pattern conversion table 42;

FIG. 27 is an illustrative view showing contents of a table in the pattern conversion table 42;

FIG. 28 is an illustrative view showing contents of a table in the pattern conversion table 42;

FIG. 29 is an illustrative view showing contents of a table in the pattern conversion table 42; and

FIG. 30 is an illustrative view showing contents of a table in the pattern conversion table 42.

### DETAILED DESCRIPTION OF THE INVENTION

Now, embodiments of the present invention will be described in detail, with reference to the drawings.

### First Embodiment

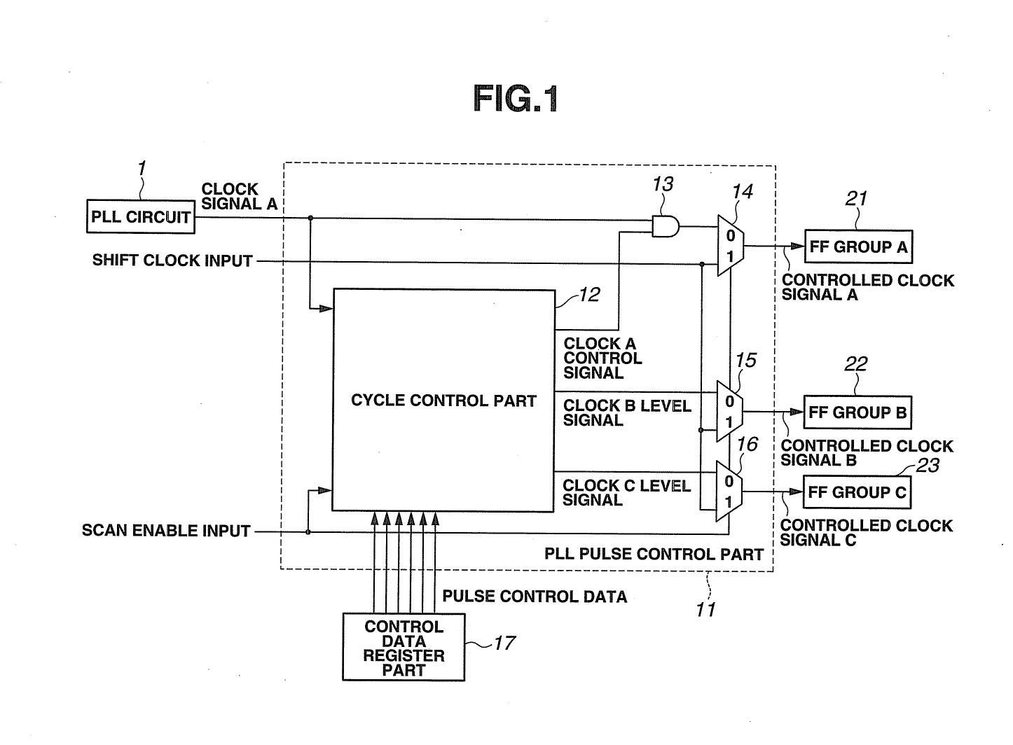

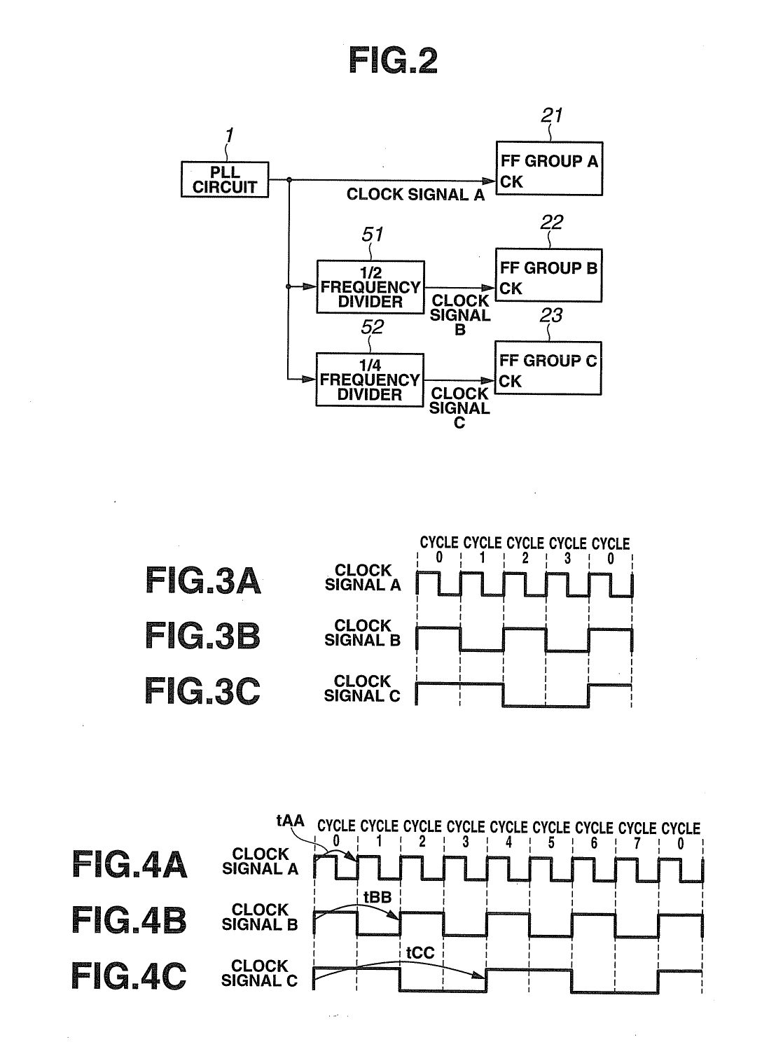

FIG. 1 is a block view showing a semiconductor integrated circuit apparatus according to a first embodiment of the present invention. FIG. 2 is a block view illustrating elements configured on the semiconductor integrated circuit apparatus in FIG. 1. FIGS. 3A to 3C show clock signals A to C which are used in a FF group A 21 to a FF group C 23 in FIG. 2. Further, FIGS. 4A to 6C are timing charts illustrating timing constraints of signal paths, i.e. clocks required for a delay fault test.

At first, the elements configured on the semiconductor integrated circuit apparatus will be described with reference to FIG. 2.

On the semiconductor integrated circuit apparatus, a PLL circuit 1 as an oscillator is configured. The PLL circuit 1 generates a clock signal A having a predetermined frequency. On the semiconductor integrated circuit apparatus, a plurality of flip-flops are configured and drive velocities required for the flip-flops are different. FIG. 2 shows an example in which the number of the flip-flop groups which operate with different clock frequencies is three.

In other words, in the example of FIG. 2, the flip-flops are grouped into a flip-flop group A (FF group A) 21 which is driven based on the clock signal A, a flip-flop group B (FF group B) 22 which is driven based on a clock signal B, and a flip-flop group C (FF group C) 23 which is driven based on a clock signal C. The clock B is a clock having a lower frequency than that of the clock A, such as a frequency equal to ½ of that of the clock A. The clock C is a clock having a lower frequency than that of the clock B, such as a frequency equal to ¼ of that of the clock A.

A ½ frequency divider 51 divides the clock signal A (FIG. 3A) from the PLL circuit 1 by 2 to generate and output the clock signal B (FIG. 3B) to the FF group B 22. A ¼ frequency divider 52 divides the clock signal A from the PLL circuit 1 by 4 to generate and output the clock signal C (FIG. 3C) to the FF group C 23.

Each flip-flop of the FF group A 21 outputs predetermined input signals in synchronization with edges of the clock signal A. Each flip-flop of the FF group B 22 outputs predetermined input signals in synchronization with edges of the clock signal B. Each flip-flop of the FF group C 23 outputs predetermined input signals which are inputted to each flip-flop, in synchronization with edges of the clock signal C.

In the semiconductor integrated circuit apparatus, the flip-flops of the FF group A 21 to the FF group C 23 are connected to one another to configure a sequential circuit. FIGS. 4A and 6C show relationships having the shortest period (timing constraints) with arrows, among relationships of clocks supplied to continuous two-step flip-flops, i.e. former and latter flip-flops, among the flip-flops in the FF group A 21 to the FF group C 23. FIGS. 4A to 4C show timing constraints in the case where the continuous two-step flip-flops are flip-flops of the same group, among the FF group A 21 to the FF group C 23.

FIG. 4A shows an example in which the former and latter flip-flops operate with the clock signal A. A timing constraint tAA in this case can be denoted by an arrow. In other words, the former flip-flop operates at a rise edge of the clock signal A of a cycle 0 that is a start point of the arrow, and the latter flip-flop operates at a rise edge of the clock signal A of a cycle 1 that is an end point of the arrow.

Similarly, FIG. 4B shows an example of a timing constraint tBB in which the former and latter flip-flops operate with the clock signal B. In other words, the former flip-flop operates at a rise edge of the clock signal B of the cycle 0 that is a start point of the arrow, and the latter flip-flop operates at a rise edge of the clock signal B of a cycle 2 that is an end point of the arrow.

Similarly, FIG. 4C shows an example of a timing constraint tCC in which the former and latter flip-flops operate with the clock signal C. The former flip-flop operates at a rise edge of the clock signal C of the cycle 0 that is a start point of the arrow, and the latter flip-flop operates at a rise edge of the clock signal C of a cycle 4 that is an end point of the arrow.

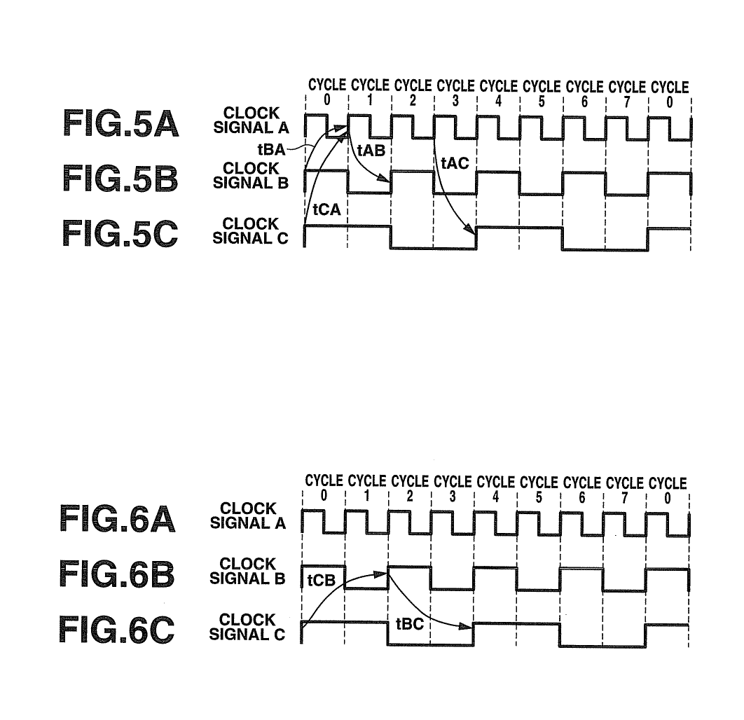

FIGS. 5A to 5C show timing constraints tBA, tAB, tCA, tAC in the case where one of the continuous two-step flip-flops is a flip-flop of the FF group A 21 and the other is a flip-flop of the FF group B 22 or the FF group C 23, among the FF group A21 to the FF group C 23. In this case, as a set of clocks which are given to the two, former and latter flip-flops, four types are conceivable as shown with arrows in FIGS. 5A to 5C: clock A and the next clock B, clock A and the next clock C, clock B and the next clock A, and clock C and the next clock A.

FIGS. 6A to 6C show timing constraints tCB, tBC in the case where one of the continuous two-step flip-flops is a flip-flop of the FF group B 22 and the other is a flip-flop of the FF group C 23, among the FF group A 21 to the FF group C 23. In the case, as a set of clocks which are given to the two, former and latter flip-flops, two types are conceivable as shown with arrows in FIGS. 6A to 6C: clock C and the next clock B, and clock B and the next clock C.

Thus, as timing constraints in the semiconductor integrated circuit apparatus having three flip-flop groups configured to operate with different frequencies wherein each flip-flop operates at rise edges and phases of clocks having different frequencies are synchronous at the rise edges, only nine patterns of timing constraints tAA to tCC shown in FIGS. 4A to 6C may be considered.

Although FIGS. 4A to 6C show the example in which the number of the flip-flop groups operating different frequencies is three, this embodiment can be applied also when the number is two, or four or more. Further, although the example in which the flip-flops operate at the rise edges of the clock signals has been described in FIGS. 4A to 6C for simplicity of description, this embodiment can be applied whether the flip-flops operate at the rise edges or at the fall edges.

This embodiment supplies two clocks for test (hereinafter referred to as controlled clock signals) corresponding to each timing constraint to each flip-flop in the delay fault test, and the embodiment enables to supply each controlled clock signal to each flip-flop, with a pulse width corresponding to the frequency of the signal.

FIG. 1 shows a semiconductor integrated circuit apparatus which can output these controlled clock signals in the delay fault test. FIG. 1 shows an example in which the number of the flip-flop groups operating different frequencies is three wherein each flip-flop operates at the rise edges and phases of clocks having different frequencies are synchronous at the rise edges.

As shown in FIG. 1, in the semiconductor integrated circuit apparatus, a PLL pulse control part 11 is provided outside of the configuration in FIG. 2. Although not shown in FIG. 1, in the semiconductor integrated circuit apparatus, the ½ frequency divider 51 and the ¼ frequency divider 52 are provided which supply the clock signals A to C to the FF group A 21 to the FF group C 23 in the normal operation, and also a selector is provided to switch between the clock signals A to C and the controlled clock signals A to C in the normal operation and in the delay fault test. Further, in the semiconductor integrated circuit apparatus in FIG. 1, in order to perform the scan test, a scan test circuit (not shown) is also provided which allows writing and reading to/from each flip-flop of the FF group A 21 to the FF group C 23.

The clock signal A from the PLL circuit 1 is provided to a cycle control part 12 and an AND circuit 13 in the PLL pulse control part 11. Scan enable input and pulse control data are also provided to the cycle control part 12. The scan enable input is a signal which switches between scan shift operation and function operation if a scan test utilizing a scan chain is performed among the fault tests, and the scan enable input is at high level (hereinafter referred to as H level) in the scan shift and at low level (hereinafter referred to as L level) in the function operation.

In the delay fault test, continuous two controlled clock signals are provided to the former and latter flip-flops. Change in the value generated in the former flip-flop by the first controlled clock signal (hereinafter also referred to as launch clock) is checked to determine whether the change is captured by the latter flip-flop or not, by the next controlled clock signal (hereinafter also referred to as capture clock).

The pulse control data includes information configured to generate the launch clock and the capture clock with a timing based on the above described timing constraints in accordance with configuration of the FF group A 21 to the FF group C 23. A control data register part 17 as a storage part stores this pulse control data. The control data register part 17 supplies the pulse control data configured to generate the launch clock and the capture clock for each predetermined cycle, to the cycle control part 12. The cycle control part 12 uses the pulse control data to output signals having pulse widths corresponding to periods of the launch clock and the capture clock, with the timing based on the timing constraint.

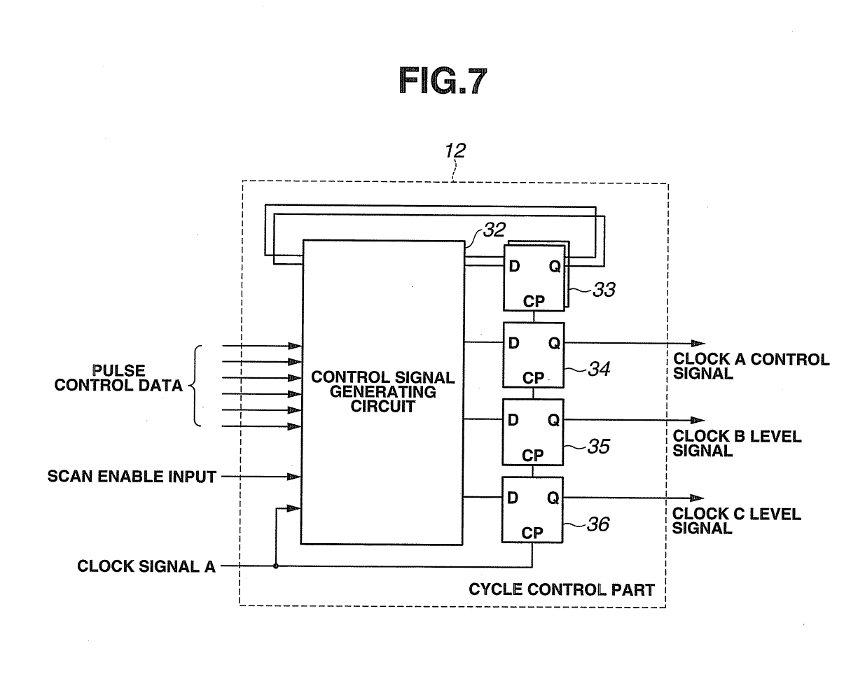

FIG. 7 is a block view showing a concrete configuration of the cycle control part 12 in FIG. 1.

The cycle control part 12 is configured by a control signal generating circuit 32, a state register 33, and flip-flops 34 to 36. The clock signal A, the scan enable input and the pulse control data are inputted to the control signal generating circuit 32, and the control signal generating circuit 32 outputs signals corresponding to these inputs.

The control signal generating circuit 32 operates with a predetermined cycle corresponding to the clock signal A and changes the output state for each cycle. The state register 33 stores information which represents what number cycle the present cycle is, and indicates the next cycle to the control signal generating circuit 32. Outputs of the control signal generating circuit 32 are synchronized and outputted by the flip-flops 34 to 36.

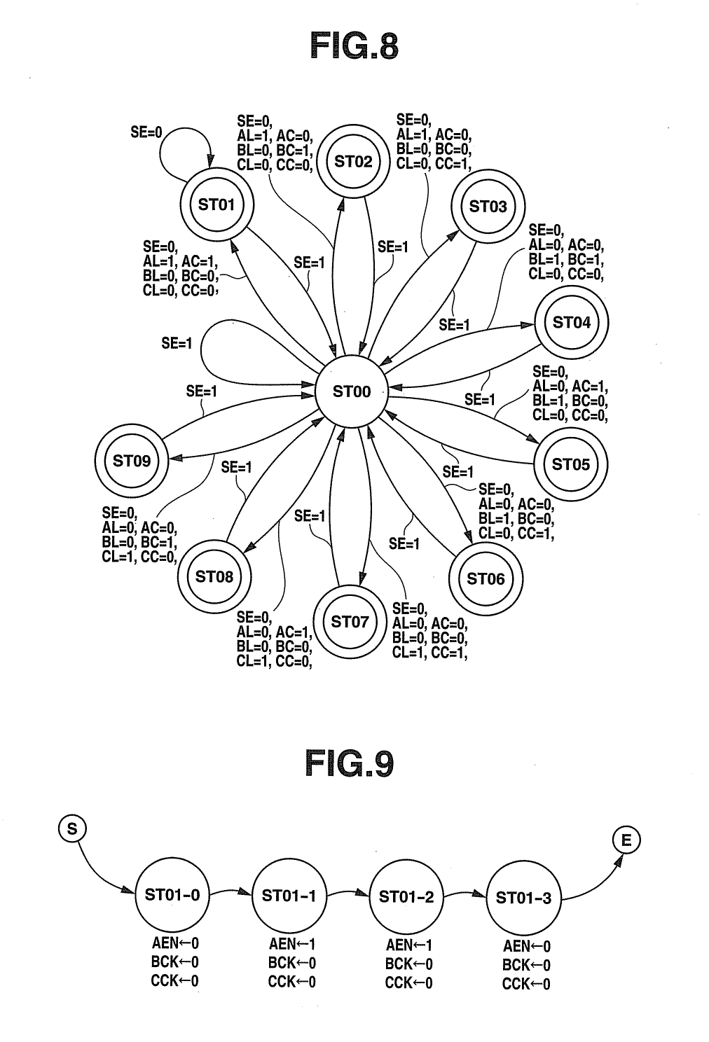

For example, the control signal generating circuit 32 can be configured by a state machine whose output state changes for each predetermined cycle, based on the clock signal A and the pulse control data. FIGS. 8 and 9 are state transition diagrams illustrating output states of the control signal generating circuit 32 which is configured by such a state machine. FIG. 8 is a state transition diagram of a top hierarchy in which the control signal generating circuit 32 begins to operate from a state ST00 when reset.

FIG. 8 shows a state diagram with a circle and substate diagrams with double circles. In FIG. 8, SE denotes scan enable input, and AL to CL and AC to CC denote pulse control data. AL to CL denote data configured to output respective controlled clock signals A to C as the launch clocks and AC to CC denote data configured to output respective controlled clock signals A to C as the capture clocks. In FIG. 8, “=” denotes transition condition in which transition between states is generated if both sides of “=” match. A plurality of conditional expressions may be combined with AND, OR, etc. In FIG. 8, AND condition is denoted by “,”.

FIG. 8 shows an example of the case where the launch clock and the capture clock which satisfy the above describe nine timing constraints tAA to tCC shown in FIGS. 4A to 6C are outputted. The timing constraints tAA to tCC are realized by substates ST01 to ST09, respectively. The state ST00 denotes an initial state.

When the scan enable input becomes to L level (SE=0), the state proceeds from the state ST00 to the substates ST01 to ST09 corresponding to the control data. The substate ST01 is an example of the case where the controlled clock signal A is selected for both the launch clock and the capture clock, so that the timing constraint tAA in FIG. 4A is realized.

Similarly, the substate ST02 is an example of the case where the controlled clock signal A is selected as the launch clock and the controlled clock signal B is selected as the capture clock, so that the timing constraint tAB shown in FIGS. 5A and 5B is realized.

Similarly, the substate ST03 is an example of the case where the controlled clock signal A is selected as the launch clock and the controlled clock signal C is selected as the capture clock, so that the timing constraint tAC shown in FIGS. 5A and 5C is realized.

Similarly, the substate ST04 is an example of the case where the controlled clock signal B is selected as the launch clock and the controlled clock signal B is selected as the capture clock, so that the timing constraint tBB shown in FIG. 4B is realized.

Similarly, the substate ST05 is an example of the case where the controlled clock signal B is selected as the launch clock and the controlled clock signal A is selected as the capture clock, so that the timing constraint tBA shown in FIGS. 5B and 5A is realized.

Similarly, the substate ST06 is an example of the case where the controlled clock signal B is selected as the launch clock and the controlled clock signal C is selected as the capture clock, so that the timing constraint tBC shown in FIGS. 6B and 6C is realized.

Similarly, the substate ST07 is an example of the case where the controlled clock signal C is selected as the launch clock and the controlled clock signal C is selected as the capture clock, so that the timing constraint tCC shown in FIG. 4C is realized.

Similarly, the substate ST08 is an example of the case where the controlled clock signal C is selected as the launch clock and the controlled clock signal A is selected as the capture clock, so that the timing constraint tCA shown in FIGS. 5C and 5A is realized.

Similarly, the substate ST09 is an example of the case where the controlled clock signal C is selected as the launch clock and the controlled clock signal B is selected as the capture clock, so that the timing constraint tCB shown in FIGS. 6C and 6B is realized.

FIG. 9 shows a concrete configuration of the substate ST01. In FIG. 9, AEN denotes a clock A control signal which permits output of the controlled clock signal A, and BCK, CCK denote a clock B level signal and a clock C level signal which determine outputs of the controlled clock signals B, C, respectively. In FIG. 9, arrows pointing to the left denote that values in the right side are assigned to the clock A control signal, the clock B level signal, and the clock C level signal.

In the lower hierarchy shown in FIG. 9, a state S and a state E are provided. The state S represents a start state of the lower hierarchy when the upper hierarchy becomes active. The state E represents that processing in the lower hierarchy is ended and control proceeds to the upper hierarchy shown in FIG. 8.

When the substate ST01 is selected by the transition condition shown in FIG. 8, the state proceeds from the start state S of the substate to a state ST01-0 which denotes a dummy cycle of the substate ST01. The state ST01-0 resets all values, AEN, BCK, CCK to 0. In the next cycle, the state proceeds to a state ST01-1 where 1 is assigned to AEN. Thereby, the clock A control signal shifts to H level in this cycle. The clock A control signal is supplied to the flip-flop 34 and outputted in synchronization with the clock signal A.

In the next cycle, the state proceeds to a state ST01-2 where 1 is assigned to AEN, in the same manner as the prior cycle. As a result, the clock A control signal shifts to H level. The clock A control signal is supplied to the flip-flop 34 and outputted in synchronization with the clock signal A.

In the next cycle, the state proceeds to a state ST01-3 where all values, AEN, BCK, CCK are reset to 0. Finally, the state proceeds to the end state E and the state changes to the initial state ST00 of the upper hierarchy.

Thus, for example, if pulse control data of AL, AC=1 and BL, CL, BC, CC=0 is inputted to the cycle control part 12 as the pulse control data, the state changes to the substate ST01 and the clock A control signal of H level is outputted from the cycle control part 12 in a predetermined cycle and the clock A control signal of H level is outputted in the next cycle.

In FIG. 1, the clock A control signal is provided to the AND circuit 13. The clock A is also provided from the PLL circuit 1 to the AND circuit 13. The AND circuit 13 outputs the clock A during the period in which the clock A control signal is at H level. The output of the AND circuit 13 is supplied to a selector 14. A shift clock input is also inputted to the selector 14. The shift clock input is a clock from an external tester (not shown) and is used in the scan shift. The selector 14 is controlled by the scan enable input and the selector 14 selects and outputs the shift clock input in the scan shift operation where the scan enable input is at H level while the selector 14 selects the output of the AND circuit 13 in the function operation where the scan enable input is at L level.

Thus, in the function operation, the clock signal A is outputted as the controlled clock signal A from the selector 14 in the cycle in which the clock A control signal is at H level. The output of the selector 14 is supplied to the FF group A 21.

The clock B level signal and the clock C level signal from the cycle control part 12 are supplied to the respective selectors 15, 16. The shift clock input is also inputted to the selectors 15, 16. The selectors 15, 16 select and output the shift clock input if the scan enable input directs the scan shift operation and the selectors 15, 16 select and output the clock B level signal or clock C level signal if the scan enable input directs the function operation.

In this embodiment, the clock B level signal is controlled to keep H level during one cycle period of the clock signal A, and the selector 15 outputs the controlled clock signal B having the same pulse width as that of the clock signal B, in the function operation. The clock C level signal is controlled to keep H level during two cycle periods of the clock signal A, and the selector 16 outputs the controlled clock signal C having the same pulse width as that of the clock signal C, in the function operation. Although a duty ratio (a ratio of H level period and L level period) of the clock signal B and the clock signal C is 1:1 in this description, the duty ratio can be varied with one cycle period of the clock signal A as an unit.

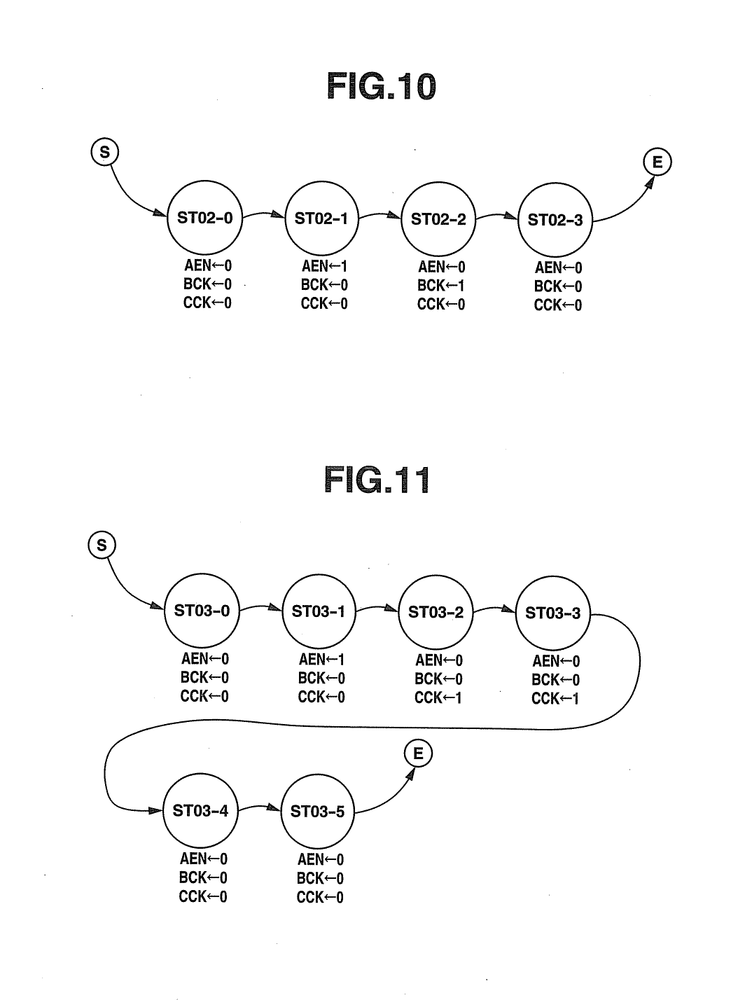

FIG. 10 is a state transition diagram showing a concrete configuration of the substate ST02, as an example of a substate diagram which outputs output including the clock B level signal. Symbols in FIG. 10 are the same as that in FIG. 9.

When the substate ST02 is selected by the transition condition shown in FIG. 8, the state proceeds from the start state S of the substate to a state ST02-0 which denotes a dummy cycle of the substate ST02. The state ST02-0 resets all values, AEN, BCK, CCK to 0. In the next cycle, the state proceeds to a state ST02-1 where 1 is assigned to AEN. Thereby, the clock A control signal shifts to H level in this cycle. The clock A control signal is supplied to the flip-flop 34 and outputted in synchronization with the clock signal A.

In the next cycle, the state proceeds to a state ST02-2 where 0 is assigned to AEN and 1 is assigned to BCK. As a result, in this cycle, the clock A control signal shifts to L level and the clock B level signal shifts to H level. The clock B level signal is supplied to the flip-flop 35 and outputted in synchronization with the clock signal A.

In the next cycle, the state proceeds to a state ST02-3 where all values, AEN, BCK, CCK are reset to 0. Finally, the state proceeds to the end state E and the state changes to the initial state ST00 of the upper hierarchy.

Thus, for example, if pulse control data of AL, BC=1 and BL, CL, AC, CC=0 is inputted to the cycle control part 12 as the pulse control data, the state changes to the substate ST02 and the clock A control signal of H level is outputted from the cycle control part 12 in a predetermined cycle and the clock B level signal of H level is outputted in the next cycle. Thus, the clock B level signal keeps H level during one cycle period.

The clock B level signal from the cycle control part 12 is supplied to the selector 15. The selector 15 outputs the clock B level signal as the controlled clock signal B if the scan enable input directs the function operation. Because the clock B level signal is at H level during one cycle period, the controlled clock signal B has a pulse width of one cycle period, i.e. duration of one period of the clock signal A.

FIG. 11 is a state transition diagram showing a concrete configuration of the substate ST03, as an example of a substate diagram which outputs output including the clock C level signal. Symbols in FIG. 11 are the same as that in FIG. 9.

When the substate ST03 is selected by the transition condition shown in FIG. 8, the state proceeds from the start state S of the substate to a state ST03-0 which denotes a dummy cycle of the substate ST03. The state ST03-O resets all values, AEN, BCK, CCK to 0. In the next cycle, the state proceeds to a state ST03-1 where 1 is assigned to AEN. Thereby, the clock A control signal shifts to H level in this cycle. The clock A control signal is supplied to the flip-flop 34 and outputted in synchronization with the clock signal A.

In the next cycle, the state proceeds to a state ST03-2 where 0 is assigned to AEN and 1 is assigned to CCK. As a result, in this cycle, the clock A control signal shifts to L level and the clock C level signal shifts to H level. The clock C level signal is supplied to the flip-flop 36 and outputted in synchronization with the clock signal A.

In the next cycle, the state proceeds to a state ST03-3 where 1 is assigned to CCK, in the same manner as the prior cycle. As a result, in this cycle, the clock C level signal keeps H level. The clock C level signal is supplied to the flip-flop 36 and outputted in synchronization with the clock signal A.

In the next cycle, the state proceeds to a state ST03-4 where 0 is assigned to CCK. As a result, in this cycle, the clock C level signal shifts to L level. The clock C level signal is supplied to the flip-flop 36 and outputted in synchronization with the clock signal A. Further, in the next cycle, the state proceeds to a state ST03-5 where 0 is assigned to CCK, in the same manner as the prior cycle. As a result, also in this cycle, the clock C level signal keeps L level. The clock C level signal is supplied to the flip-flop 36 and outputted in synchronization with the clock signal A. Finally, the state proceeds to the end state E and the state changes to the initial state ST00 of the upper hierarchy.

Thus, for example, if pulse control data of AL, CC=1 and BL, CL, AC, BC=0 is inputted to the cycle control part 12 as the pulse control data, the state changes to the substate ST03 and the clock A control signal of H level is outputted from the cycle control part 12 in a predetermined cycle. Then, the clock C level signal of H level is outputted in the next two cycles and the clock C level signal of L level is outputted in the next two cycles. Thus, the clock C level signal keeps H level during two cycle periods and keeps L level during two cycle periods.

The clock C level signal from the cycle control part 12 is supplied to the selector 16. The selector 16 outputs the clock C level signal as a controlled clock signal C if the scan enable input directs the function operation. Because the clock C level signal is at H level during two cycle periods, the controlled clock signal C has a pulse width of two cycle periods, i.e. duration of two periods of the clock signal A.

The controlled clock signal B and the controlled clock signal C from the selectors 15, 16 are supplied to the respective FF group B 22 and FF group C 23.

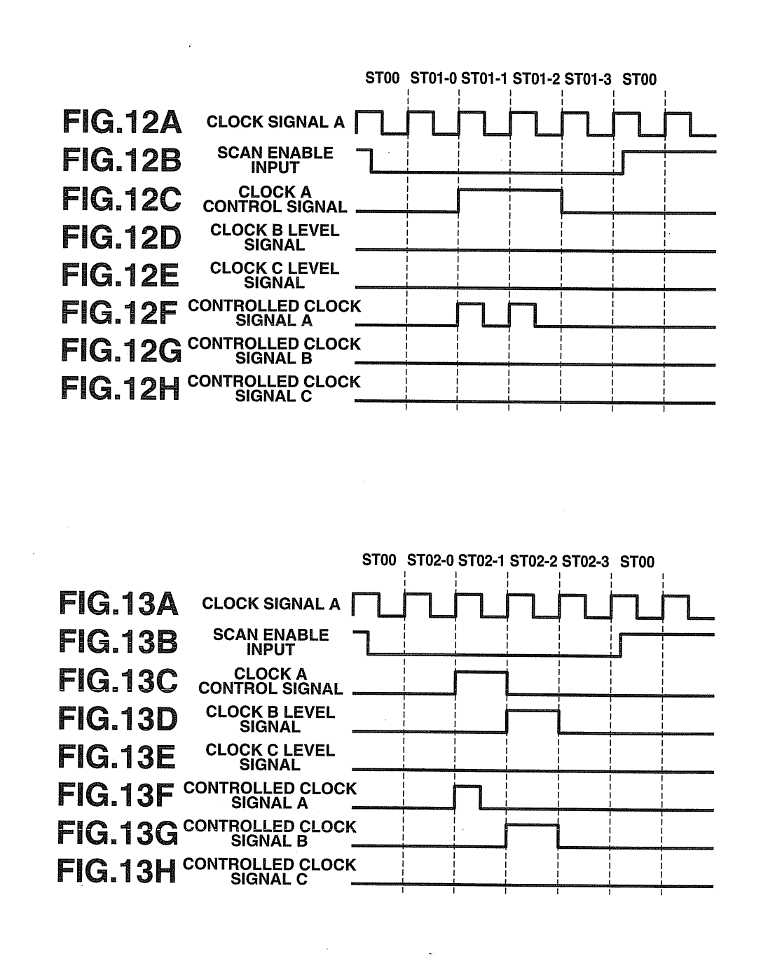

Then, operation of the embodiment configured in such a manner will be described with reference to timing charts in FIGS. 12A to 20H. FIGS. 12A to 20H illustrate the timing constraints tAA, tAB, tAC, tBB, tBA, tBC, tCC, tCA, tCB, respectively.

In the normal operation, the semiconductor integrated circuit apparatus has the same configuration as in FIG. 2. In this case, the clock signal A from the PLL circuit 1 is supplied to the flip-flops of the FF group A 21, the clock signal B is supplied to the flip-flops of the FF group B 22, and the clock signal C is supplied to the flip-flops of the FF group C 23.

In the test mode, the scan shift operation and the function operation are directed by the scan enable input. In the scan shift, the scan enable input becomes to H level and all of the selectors 14 to 16 select and supply the shift clock input to the respective FF group A 21 to FF group C 23. In the scan shift, a scan chain is configured by the flip-flops of the FF group A 21 to the FF group C 23.

Further, utilizing the scan chain, values used in the delay fault test are set for the flip-flops. In the control data register part 17, pulse control data used in the delay fault test is set.

In the function operation, the scan enable input becomes to L level. The clock signal A and the pulse control data are supplied to the control signal generating circuit 32 of the cycle control part 12, and the control signal generating circuit 32 determines output state based on the pulse control data, for each cycle based on the clock signal A, when the scan enable becomes to L level.

It is here assumed that pulse control data configured to generate the launch pulse and the capture pulse corresponding to the timing constraint tAA in FIG. 4A is inputted to the control signal generating circuit 32. Thus, in this case, AL, AC=1 and BL, CL, BC, CC=0. In this case, when the scan enable input becomes to L level (SE=0), the control signal generating circuit 32 shifts to the state ST01 in FIG. 8 in accordance with the pulse control data and executes the states S, ST01-1 to ST01-3, E shown in FIG. 9. In other words, the PLL pulse control part 11 performs an operation shown in FIGS. 12A to 12H.

As shown in FIGS. 12A to 12H, AEN (clock A control signal), BCK (clock B level signal), CCK (clock C level signal) are initialized to 0 in the state ST01-0, and 1 is assigned to AEN in the state ST01-1. Also in the state ST01-2, AEN is continuously kept at 1. As a result, as shown in FIGS. 12A to 12H, the clock A control signal is at H level during two cycle periods of the states ST01-1, ST01-2. On the other hand, the clock B level signal and the clock C level signal remains at L level.

The clock A control signal is provided to the AND circuit 13 and the clock signal A is supplied to the selector 14 during two cycle periods of the states ST01-1, ST01-2. Therefore, the clock signal A is continuously outputted as the controlled clock signal A from the selector 14 during the two cycle periods. In this way, the launch clock and the capture clock corresponding to the timing constraint tAA in FIG. 4A can be provided to the FF group 21.

Next, it is assumed that pulse control data configured to generate the launch pulse and the capture pulse corresponding to the timing constraint tAB in FIGS. 5A and 5B is inputted to the control signal generating circuit 32. Thus, in this case, AL, BC=1 and BL, CL, AC, CC=0. In this case, when the scan enable input becomes to L level (SE 0), the control signal generating circuit 32 shifts to the state ST02 in FIG. 8 in accordance with the pulse control data. Then, the PLL pulse control part 11 performs an operation shown in FIGS. 13A to 13H.

In other words, as shown in FIGS. 13A to 13H, AEN (clock A control signal), BCK (clock B level signal), CCK (clock C level signal) are initialized to 0 in the state ST02-0, and 1 is assigned to AEN in the state ST02-1. Then, in the state ST02-2, AEN is returned to 0 while 1 is assigned to BCK. As a result, as shown in FIGS. 13A to 13H, the clock A control signal is at H level in the state ST02-1 and the clock B level signal is at H level in the state ST02-2.

The clock A control signal is provided to the AND circuit 13 and the clock signal A is outputted as the controlled clock signal A in the state ST02-1. The clock B level signal is provided to the selector 15 and the controlled clock signal B of H level is outputted during one cycle period of the state ST02-2. The controlled clock signal A is supplied to the flip-flops of the FF group A 21 and the controlled clock signal B is supplied to the flip-flops of the FF group B 22. In this way, the delay fault test can be performed with the launch clock and the capture clock corresponding to the timing constraint tAB in FIGS. 5A, 5B.

In this case, the controlled clock signal B has the pulse width of the original clock signal B, so that the delay fault test can be reliably performed.

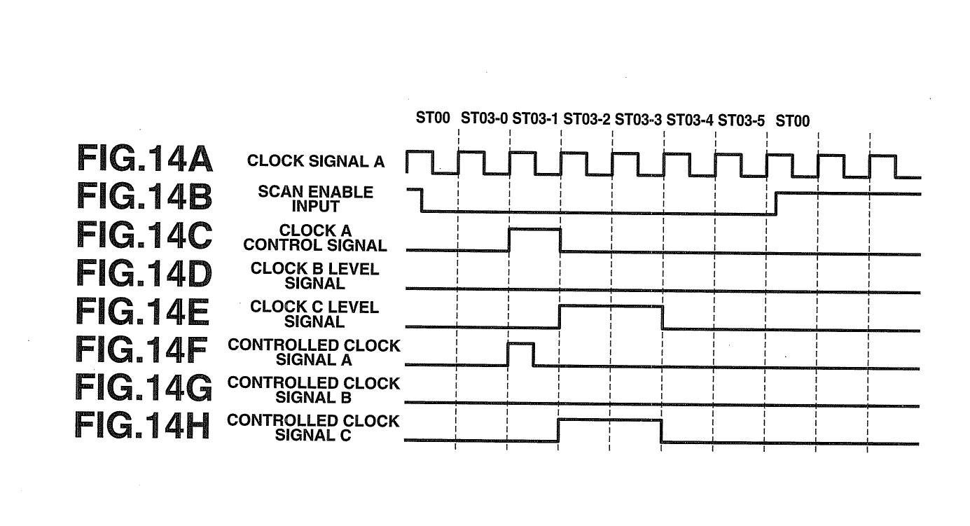

Then, it is assumed that pulse control data configured to generate the launch pulse and the capture pulse corresponding to the timing constraint tAC in FIGS. 5A, 5C is inputted to the control signal generating circuit 32. Thus, in this case, AL, CC=1 and BL, CL, AC, BC=0. In this case, when the scan enable input becomes to L level (SE 0), the control signal generating circuit 32 shifts to the state ST03 in FIG. 8 in accordance with the pulse control data. Then, the PLL pulse control part 11 performs an operation shown in FIGS. 14A to 14H.

In other words, as shown in FIGS. 14A to 14H, AEN (clock A control signal), BCK (clock B level signal), CCK (clock C level signal) are initialized to 0 in the state ST03-0, and 1 is assigned to AEN in the state ST03-1. Then, in the state ST03-2, AEN is returned to 0 while 1 is assigned to CCK. Further, in the next state ST03-3, 1 is continuously assigned to CCK. As a result, as shown in FIGS. 14A to 14H, the clock A control signal is at H level in the state ST03-1, and the clock C level signal is at H level in the states ST03-2, ST03-3.

The clock A control signal is provided to the AND circuit 13 and the clock signal A is outputted as the controlled clock signal A in the state ST03-1. The clock C level signal is provided to the selector 16 and the controlled clock signal C of H level is outputted during two cycle periods of the states ST03-2, ST03-3. The controlled clock C is supplied to the flip-flops of the FF group C 23. In this way, the delay fault test can be performed with the launch clock and the capture clock corresponding to the timing constraint tAC in FIGS. 5A, 5C.

In this case, the controlled clock signal C has the pulse width of the original clock signal C, so that the delay fault test can be reliably performed.

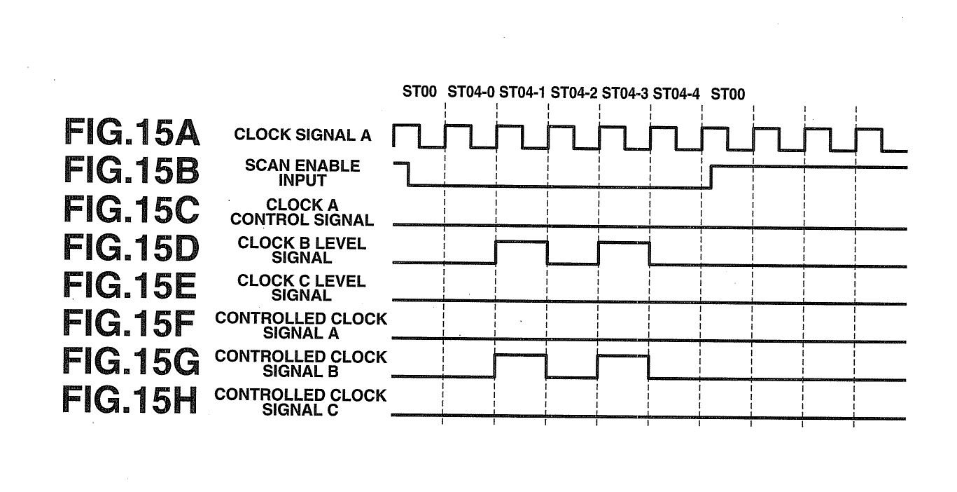

Then, it is assumed that pulse control data configured to generate the launch pulse and the capture pulse corresponding to the timing constraint tBB in FIG. 4B is inputted to the control signal generating circuit 32. Thus, in this case, BL, BC=1, and AL, CL, AC, CC=0. In this case, when the scan enable input becomes to L level (SE=0), the control signal generating circuit 32 shifts to the state ST04 in FIG. 8 in accordance with the pulse control data. Then, the PLL pulse control part 11 performs an operation shown in FIGS. 15A to 15H.

In other words, as shown in FIGS. 15A to 15H, AEN (clock A control signal), BCK (clock B level signal), CCK (clock C level signal) are initialized to 0 in a state ST04-0, and 1 is assigned to BCK in a state ST04-1. Then, BCK is returned to 0 in a state ST04-2, and 1 is assigned to BCK in a next state ST04-3. Further, BCK is returned to 0 in a state ST04-4. As a result, as shown in FIGS. 15A to 15H, the clock B level signal is at H level in the states ST04-1, ST04-3.

The clock B level signal is provided to the selector 15 and the controlled clock signal B of H level is outputted during one cycle period of the state ST04-1 and during one cycle period of the state ST04-3. The controlled clock signal B is supplied to the flip-flops of the FF group B 22. In this way, the delay fault test can be performed with the launch clock and the capture clock corresponding to the timing constraint tBB in FIG. 4B.

In this case, the controlled clock signal B has the pulse width of the original clock signal B, so that the delay fault test can be reliably performed.

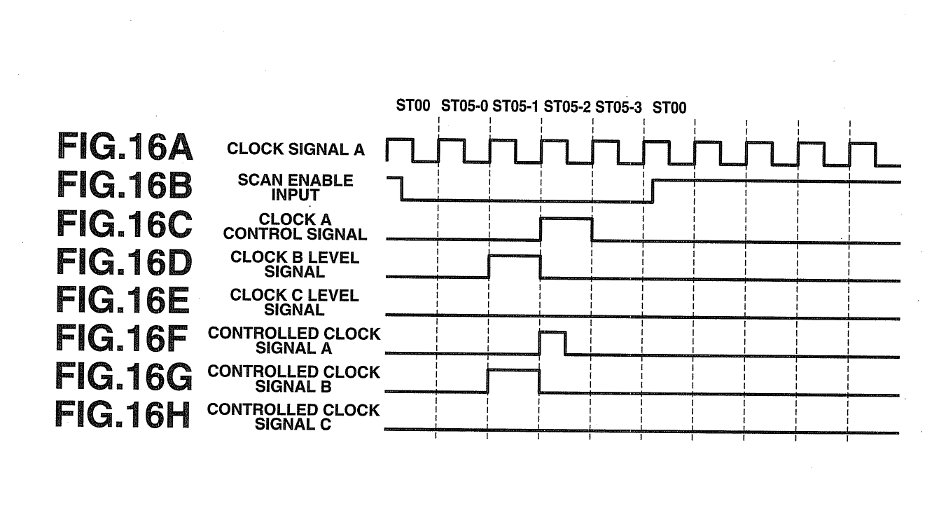

Then, it is assumed that pulse control data configured to generate the launch pulse and the capture pulse corresponding to the timing constraint tBA in FIGS. 5B, 5A is inputted to the control signal generating circuit 32. Thus, in this case, BL, AC=1, and AL, CL, BC, CC=0. In this case, when the scan enable input becomes to L level (SE=0), the control signal generating circuit 32 shifts to the state ST05 in FIG. 8 in accordance with the pulse control data. Then, the PLL pulse control part 11 performs an operation shown in FIGS. 16A to 16H.

In other words, as shown in FIGS. 16A to 16H, AEN (clock A control signal), BCK (clock B level signal), CCK (clock C level signal) are initialized to 0 in a state ST05-0, and 1 is assigned to BCK in a state ST05-1. Then, in a state ST05-2, BCK is returned to 0 while 1 is assigned to AEN. As a result, as shown in FIGS. 16A to 16H, the clock B level signal is at H level in the state ST05-1, and the clock A control signal is at H level in the state ST05-2.

The clock B level signal is provided to the selector 15 and the controlled clock signal B of H level is outputted during one cycle period of the state ST05-1. The clock A control signal is provided to the AND circuit 13 and the clock signal A is outputted as the controlled clock signal A in the state ST05-2. The controlled clock signal A is supplied to the flip-flops of the FF group A 21 and the controlled clock signal B is supplied to the flip-flops of the FF group B 22. In this way, the delay fault test can be performed with the launch clock and the capture clock corresponding to the timing constraint tBA in FIGS. 5B, 5A.

In this case, the controlled clock signal B has the pulse width of the original clock signal B, so that the delay fault test can be reliably performed.

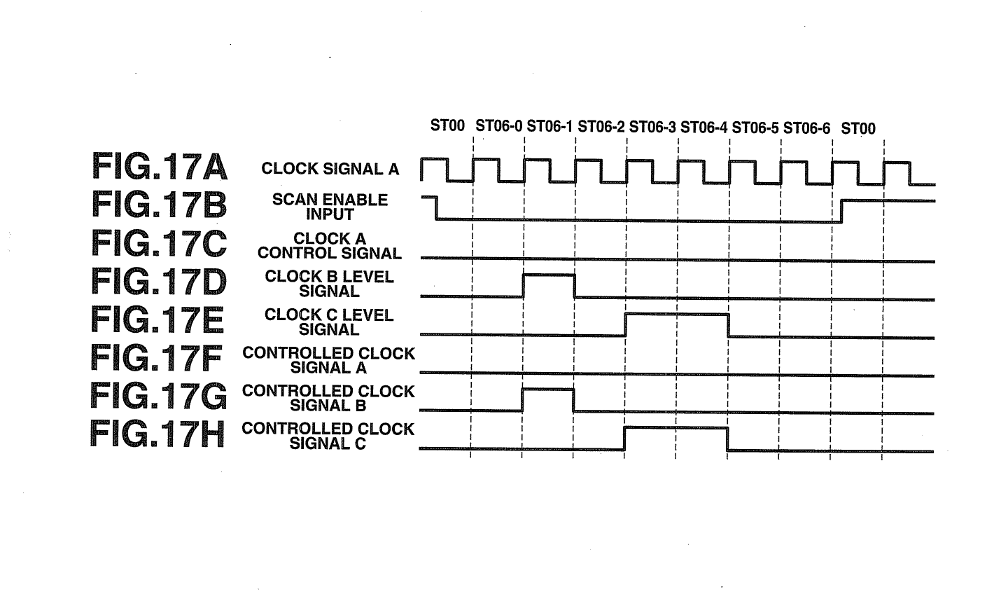

Then, it is assumed that pulse control data configured to generate the launch pulse and the capture pulse corresponding to the timing constraint tBC in FIGS. 5B, 5C is inputted to the control signal generating circuit 32. Thus, in this case, BL, CC=1, and AL, CL, AC, BC=0. In this case, when the scan enable input becomes to L level (SE=0), the control signal generating circuit 32 shifts to the state ST06 in FIG. 8 in accordance with the pulse control data. Then, the PLL pulse control part 11 performs an operation shown in FIGS. 17A to 17H.

In other words, as shown in FIGS. 17A to 17H, AEN (clock A control signal), BCK (clock B level signal), CCK (clock C level signal) are initialized to 0 in a state ST06-0, and 1 is assigned to BCK in a state ST06-1. Then, BCK is returned to 0 in a state ST06-2. Then, 1 is assigned to CCK in a state ST06-3. Further, 1 is continuously assigned to CCK in a next state ST06-4. As a result, as shown in FIGS. 17A to 17H, the clock B level signal is at H level in the state ST06-1, and the clock C level signal is at H level in the states ST06-3, ST06-4.

The clock B level signal is provided to the selector 15 and the controlled clock signal B of H level is outputted during one cycle period of the state ST06-1. The clock C level signal is provided to the selector 16 and the controlled clock signal C of H level is outputted during two cycle periods of the states ST06-3, ST06-4. The controlled clock signal A is supplied to the flip-flops of the FF group A 21 and the controlled clock signal C is supplied to the flip-flops of the FF group C 23. In this way, the delay fault test can be performed with the launch clock and the capture clock corresponding to the timing constraint tBC in FIGS. 5B, 5C.

In this case, the controlled clock signal B has the pulse width of the original clock signal B and the controlled clock signal C has the pulse width of the original clock signal C, so that the delay fault test can be reliably performed.

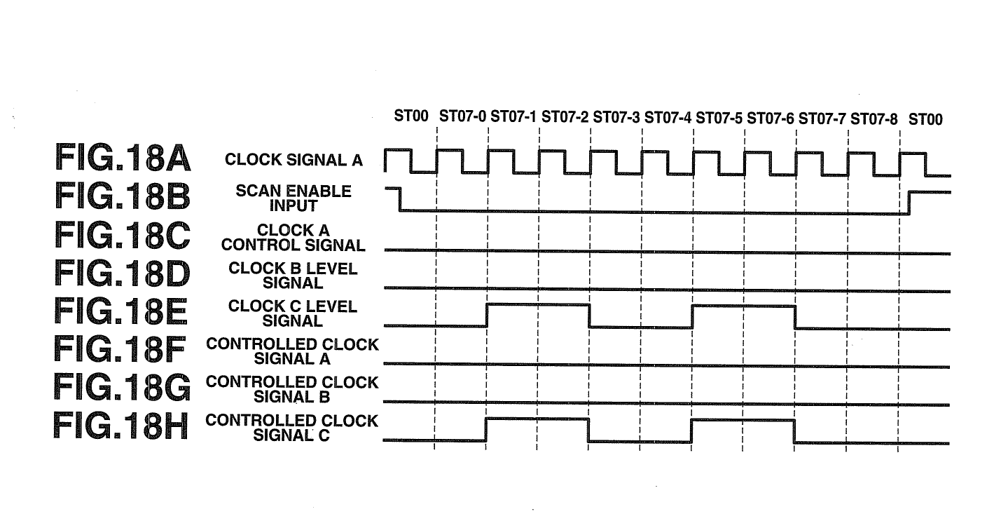

Then, it is assumed that pulse control data configured to generate the launch pulse and the capture pulse corresponding to the timing constraint tCC in FIG. 4C is inputted to the control signal generating circuit 32. Thus, in this case, CL, CC=1, and AL, BL, AC, BC=0. In this case, when the scan enable input becomes to L level (SE=0), the control signal generating circuit 32 shifts to the state ST07 in FIG. 8 in accordance with the pulse control data. Then, the PLL pulse control part 11 performs an operation shown in FIGS. 18A to 18H.

In other words, as shown in FIGS. 18A to 18H, AEN (clock A control signal), BCK (clock B level signal), CCK (clock C level signal) are initialized to 0 in a state ST07-0, and 1 is assigned to CCK in a state ST07-1. Then, 1 is continuously assigned to CCK also in a state ST07-2. Further, CCK is returned to 0 in states ST07-3, ST07-4, and thereafter 1 is assigned to CCK in states ST07-5, ST07-6. As a result, as shown in FIGS. 18A to 18H, the clock C level signal is continuously at H level in the states ST07-1, ST07-2, and the clock C level signal is continuously at H level in the states ST07-5, ST07-6, also.

The clock C level signal is provided to the selector 16 and the controlled clock signal of H level is outputted during two cycle periods of the states ST07-1, ST07-2, and further the controlled clock signal of H level is outputted during two cycle periods of the states ST07-5, ST07-6. In this way, the delay fault test can be performed with the launch clock and the capture clock corresponding to the timing constraint tCC in FIG. 4C.

In this case, the controlled clock signal C has the pulse width of the original clock signal C, so that the delay fault test can be reliably performed.

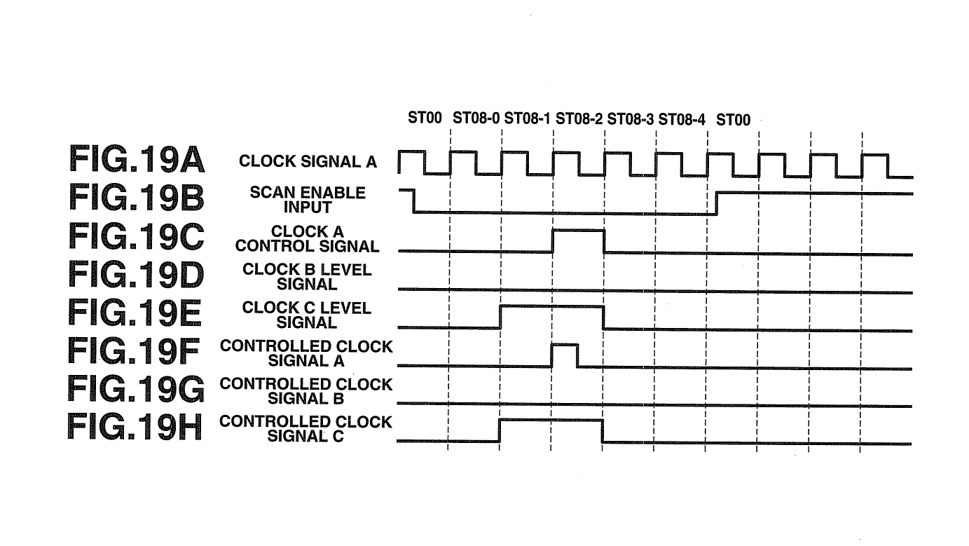

Then, it is assumed that pulse control data configured to generate the launch pulse and the capture pulse corresponding to the timing constraint tCA in FIGS. 5C, 5A is inputted to the control signal generating circuit 32. Thus, in this case, CL, AC=1, and AL, BL, BC, CC=0. In this case, when the scan enable input becomes to L level (SE=0), the control signal generating circuit 32 shifts to the state ST08 in FIG. 8 in accordance with the pulse control data. Then, the PLL pulse control part 11 performs an operation shown in FIGS. 19A to 19H.

In other words, as shown in FIGS. 19A to 19H, AEN (clock A control signal), BCK (clock B level signal), CCK (clock C level signal) are initialized to 0 in a state ST08-0, and 1 is assigned to CCK in a state ST08-1. Then, also in a state ST08-2, 1 is continuously assigned to CCK while 1 is assigned to AEN. As a result, as shown in FIGS. 19A to 19H, the clock C level signal is at H level in the states ST08-1, ST08-2, and the clock A control signal is also at H level in the state ST08-2.

The clock C level signal is provided to the selector 16 and the controlled clock signal C of H level is outputted during two cycle periods of the states ST08-1, ST08-2. Further, the clock A control signal is provided to the AND circuit 13 and the clock signal A is outputted as the controlled clock signal A in the state ST08-2. The controlled clock signal A is supplied to the flip-flops of the FF group A 21 and the controlled clock signal C is supplied to the flip-flops of the FF group C 23. In this way, the delay fault test can be performed with the launch clock and the capture clock corresponding to the timing constraint tCA in FIGS. 5C, 5A.

In this case, the controlled clock signal C has the pulse width of the original clock signal C, so that the delay fault test can be reliably performed.

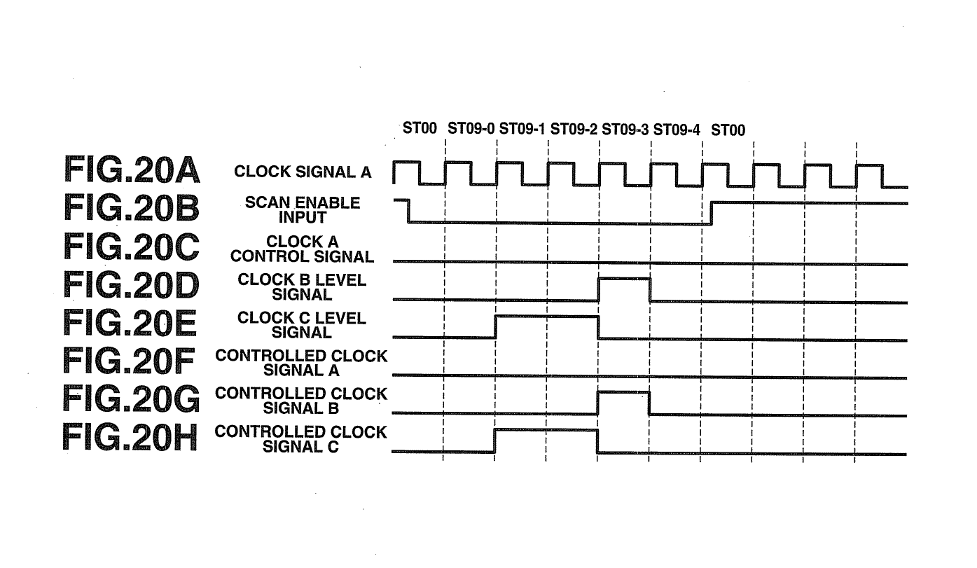

Then, it is assumed that pulse control data configured to generate the launch pulse and the capture pulse corresponding to the timing constraint tCB in FIGS. 6C, 6B is inputted to the control signal generating circuit 32. Thus, in this case, CL, BC=1, and AL, BL, AC, CC=0. In this case, when the scan enable input becomes to L level (SE 0), the control signal generating circuit 32 shifts to the state ST09 in FIG. 8 in accordance with the pulse control data. Then, the PLL pulse control part 11 performs an operation shown in FIGS. 20A to 20H.

In other words, as shown in FIGS. 20A to 20H, AEN (clock A control signal), BCK (clock B level signal), CCK (clock C level signal) are initialized to 0 in a state ST09-0, and 1 is assigned to CCK in a state ST09-1. Further, also in a state ST09-2, 1 is continuously assigned to CCK. Then, in the state ST09-3, CCK is returned to 0 while 1 is assigned to BCK. As a result, as shown in FIGS. 20A to 20H, the clock C level signal is at H level in the states ST09-1, ST09-2, and the clock B level signal is at H level in the state ST09-3.

The clock C level signal is provided to the selector 16 and the controlled clock signal C of H level is outputted during two cycle periods of the states ST09-1, ST09-2. The clock B level signal is provided to the selector 15 and the controlled clock signal B of H level is outputted during one cycle period of the state ST09-3. The controlled clock signal B is supplied to the flip-flops of the FF group B 22 and the controlled clock signal C is supplied to the flip-flops of the FF group C 23. In this way, the delay fault test can be performed with the launch clock and the capture clock corresponding to the timing constraint tCB in FIGS. 6C, 6B.

In this case, the controlled clock signal B has the pulse width of the original clock signal B and the controlled clock signal C has the pulse width of the original clock signal C, so that the delay fault test can be reliably performed.

Thus, in this embodiment, in the delay fault test in the semiconductor integrated circuit apparatus using a plurality of clocks having different frequencies, if a launch clock or a capture clock corresponding to a clock other than the clock having the highest frequency is generated, the launch clock or the capture clock having the same pulse width as the original pulse width can be generated with an adequate timing constraint, by clock width. Consequently, certainty of the delay fault test can be improved.

### Second Embodiment

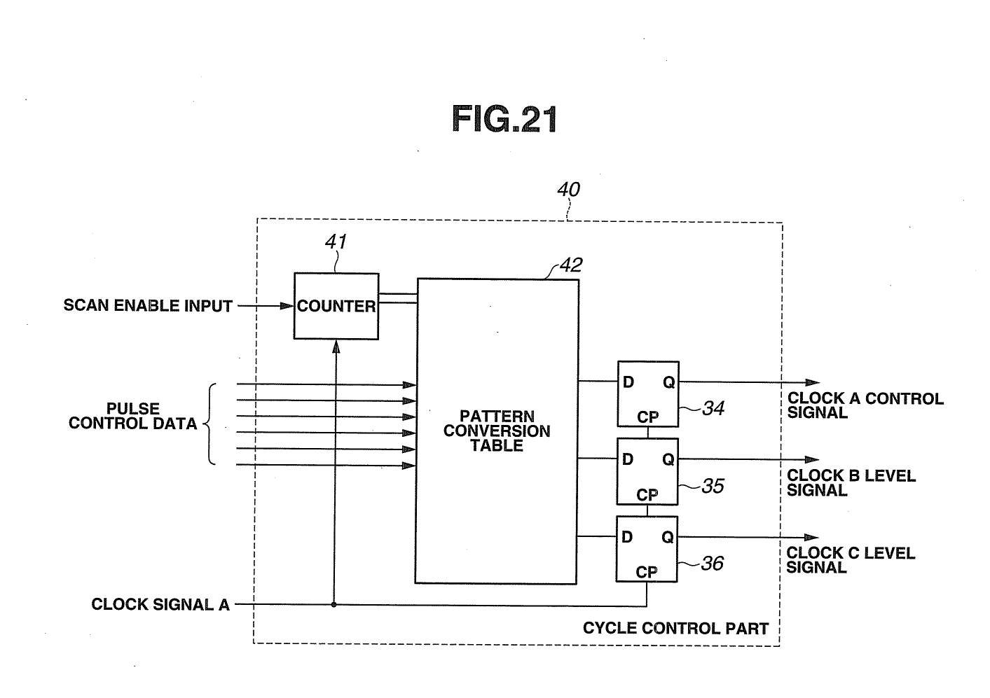

FIG. 21 is a block view showing a configuration of a cycle control part employed in a second embodiment of the present invention. In FIG. 21, the same components as that in FIG. 7 are denoted by the same symbols and the description for these components will be omitted. This embodiment has the same configuration as in FIG. 1, except for the cycle control part.

In the description of the first embodiment, the example in which the cycle control part is configured by the state machine has been described. In this embodiment, a cycle control part 40 using a conversion table instead of the state machine is employed.

The cycle control part 40 is configured by a counter 41, a pattern conversion table 42, and flip-flops 34 to 36. Scan enable input is inputted to the counter 41. When the scan enable input becomes to L level to direct the function operation, the counter 41 counts the clock signal A and notifies the pattern conversion table of the timing of a sequence of cycles.

To the pattern conversion table 42, the notification is inputted as a signal which indicates what number cycle the count output of the counter 41 is, and the clock signal A and the pulse control data are also inputted. The pattern conversion table 42 outputs a clock A control signal (AEN), a clock B level signal (BCK), and a clock C level signal (CCK) based on the pulse control data for each cycle. The clock A control signal (AEN), the clock B level signal (BCK), and the clock C level signal (CCK) are provided to the respective flip-flops 34 to 36 and outputted in synchronization with the clock signal A.

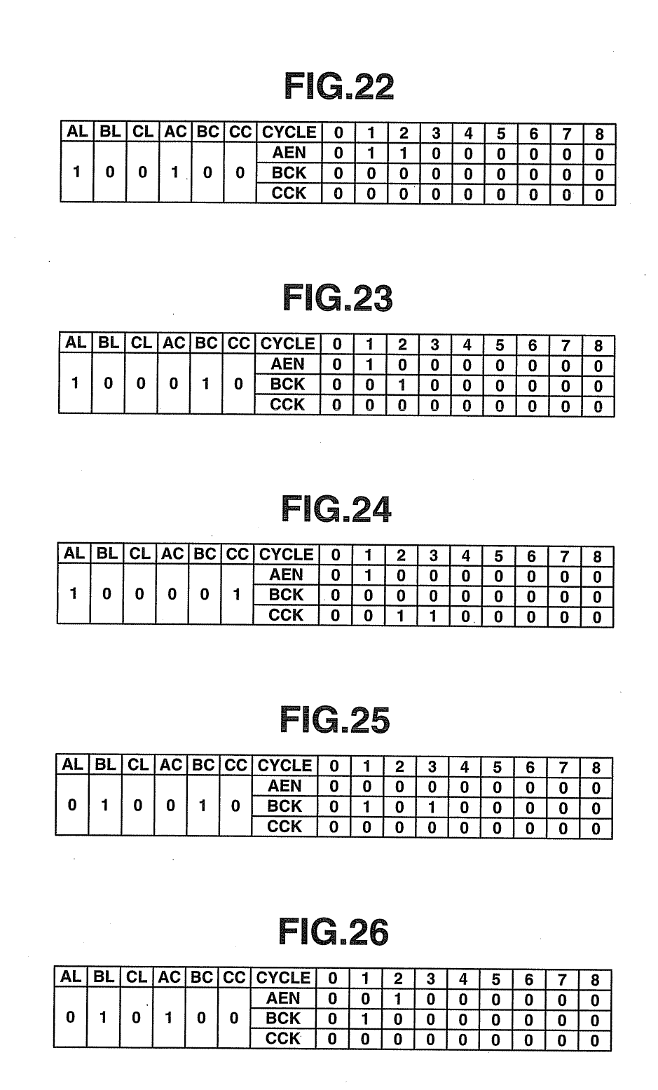

FIGS. 22 to 30 are illustrative views showing contents of tables in the pattern conversion table 42. In FIGS. 22 to 30, SE denotes scan enable input, and AL to CL and AC to CC denote pulse control data which is the same as in the first embodiment. In other words, AL to CL denote data for outputting respective controlled clock signals A to C as the launch clocks, and AC to CC denote data for outputting respective controlled clock signals A to C as the capture clocks.

FIGS. 22 to 30 show tables configured to generate the launch clocks and the capture clocks corresponding to the above described timing constraints tAA, tAB, tAC, tBB, tBA, tBC, tCC, tCA, tCB, respectively.

Next, operation of the embodiment configured in such a manner will be described.

Also in this embodiment, examples of the case of outputting the launch clocks and the capture clocks which satisfy the above described nine timing constraints tAA to tCC shown in FIGS. 4A to 6C will be described. The timing constraints tAA to tCC are realized by the tables shown in FIGS. 22 to 30, respectively.

In the function operation, the scan enable input becomes to L level. When the scan enable input becomes to L level (SE=0), the counter 41 counts the clock signal A and indicates each cycle period to the pattern conversion table 42. A signal indicating the cycle period from the counter 41 and pulse control data are inputted to the pattern conversion table 42 of the cycle control part 40.

It is here assumed that pulse control data configured to generate the launch pulse and the capture pulse corresponding to the timing constraint tAA in FIG. 4A is inputted to the pattern conversion table 42. Thus, in this case, AL, AC=1 and BL, CL, BC, CC=0. In this case, when the scan enable input becomes to L level (SE=0), the pattern conversion table 42 refers to a conversion table in FIG. 22 in accordance with the pulse control data.

In other words, as shown in FIG. 22, AEN (clock A control signal), BCK (clock B level signal), CCK (clock C level signal) are initialized to 0 in the cycle 0, and 1 is assigned to AEN in the cycle 1. Also in the cycle 2, AEN is continuously kept at 1. Thus, in this case, the operation is the same as the timing chart of the FIGS. 12A to 12H and the clock A control signal is at H level during two cycle periods of the cycles 1, 2.

The clock A control signal is provided to the AND circuit 13 and the clock signal A is supplied to the selector 14 during the two cycle periods of the cycles 1, 2. Therefore, the clock signal A is continuously outputted as the controlled clock signal A from the selector 14 during the two cycle periods. In this way, the launch clock and the capture clock corresponding to the timing constraint tAA in FIG. 4A can be provided to the FF group 21.

Then, it is assumed that pulse control data configured to generate the launch pulse and the capture pulse corresponding to the timing constraint tAB in FIGS. 5A, 5B is inputted to the pattern conversion table 42. Thus, in this case, AL, BC=1 and BL, CL, AC, CC=0. In this case, when the scan enable input becomes to L level (SE=0), the pattern conversion table 42 refers to a conversion table in FIG. 23 in accordance with the pulse control data.

In other words, as shown in FIG. 23, AEN (clock A control signal), BCK (clock B level signal), CCK (clock C level signal) are initialized to 0 in the cycle 0, and 1 is assigned to AEN in the cycle 1. Then, in the cycle 2, AEN is returned to 0 while 1 is assigned to BCK. Thus, in this case, the operation is the same as the timing chart of FIGS. 13A to 13H and the clock A control signal is at H level in the cycle 1 and the clock B level signal is at H level in the cycle 2.

The clock A control signal is provided to the AND circuit 13 and the clock signal A is outputted as the controlled clock signal A in the cycle 1. The clock B level signal is provided to the selector 15 and the controlled clock signal B of H level is outputted during one cycle period of the cycle 2. The controlled clock signal A is supplied to the flip-flops of the FF group A 21 and the controlled clock signal B is supplied to the flip-flops of the FF group B 22. In this way, the delay fault test can be performed with the launch clock and the capture clock corresponding to the timing constraint tAB in FIGS. 5A, 5B.

In this case, the controlled clock signal B has the pulse width of the original clock signal B, so that the delay fault test can be reliably performed.

Then, it is assumed that pulse control data configured to generate the launch pulse and the capture pulse corresponding to the timing constraint tAC in FIGS. 5A, 5C is inputted to the pattern conversion table 42. Thus, in this case, AL, CC=1 and BL, CL, AC, BC=0. In this case, when the scan enable input becomes to L level (SE=0), the pattern conversion table 42 refers to a conversion table in FIG. 24 in accordance with the pulse control data.

In other words, as shown in FIG. 24, AEN (clock A control signal), BCK (clock B level signal), CCK (clock C level signal) are initialized to 0 in the cycle 0, and 1 is assigned to AEN in the cycle 1. Then, in the cycle 2, AEN is returned to 0 while 1 is assigned to CCK. Further, in the next cycle 3, 1 is continuously assigned to CCK. Thus, in this case, the operation is the same as the timing chart of FIGS. 14A to 14H and the clock A control signal is at H level in the cycle 1 and the clock C level signal is at H level in the cycles 2, 3.

The clock A control signal is provided to the AND circuit 13 and the clock signal A is outputted as the controlled clock signal A in the cycle 1. The clock C level signal is provided to the selector 16 and the controlled clock signal C of H level is outputted during two cycle periods of the cycles 2, 3. The controlled clock signal A is supplied to the flip-flops of the FF group A 21 and the controlled clock signal C is supplied to the flip-flops of the FF group C 23. In this way, the delay fault test can be performed with the launch clock and the capture clock corresponding to the timing constraint tAC in FIGS. 5A, 5C.

In this case, the controlled clock signal C has the pulse width of the original clock signal C, so that the delay fault test can be reliably performed.

Then, it is assumed that pulse control data configured to generate the launch pulse and the capture pulse corresponding to the timing constraint tBB in FIG. 4B is inputted to the pattern conversion table 42. Thus, in this case, BL, BC=1 and AL, CL, AC, CC=0. In this case, when the scan enable input becomes to L level (SE=0), the pattern conversion table 42 refers to a conversion table in FIG. 25 in accordance with the pulse control data.

In other words, as shown in FIG. 25, AEN (clock A control signal), BCK (clock B level signal), CCK (clock C level signal) are initialized to 0 in the cycle 0, and 1 is assigned to BCK in the cycle 1. Then, BCK is returned to 0 in the cycle 2, and 1 is assigned to BCK in the next cycle 3. Further, BCK is returned to 0 in the cycle 4. Thus, in this case, the operation is the same as the timing chart of FIGS. 15A to 15H and the clock B level signal is at H level in the cycles 1, 3.

The clock B level signal is provided to the selector 15 and the controlled clock signal B of H level is outputted during one cycle period of the cycle 1 and during one cycle period of the cycle 3. The controlled clock signal B is supplied to the flip-flops of the FF group B 22. In this way, the delay fault test can be performed with the launch clock and the capture clock corresponding to the timing constraint tBB in FIG. 4B.

In this case, the controlled clock signal B has the pulse width of the original clock signal B, so that the delay fault test can be reliably performed.

Then, it is assumed that pulse control data configured to generate the launch pulse and the capture pulse corresponding to the timing constraint tBA in FIGS. 5B, 5A is inputted to the pattern conversion table 42. Thus, in this case, BL, AC=1 and AL, CL, BC, CC=0. In this case, when the scan enable input becomes to L level (SE=0), the pattern conversion table 42 refers to a conversion table in FIG. 26 in accordance with the pulse control data.

In other words, as shown in FIG. 26, AEN (clock A control signal), BCK (clock B level signal), CCK (clock C level signal) are initialized to 0 in the cycle 0, and 1 is +assigned to BCK in the cycle 1. Then, in the cycle 2, BCK is returned to 0 while 1 is assigned to AEN. Thus, in this case, the operation is the same as the timing chart of FIGS. 16A to 16H and the clock B level signal is at H level in the cycle 1 and the clock A control signal is at H level in the cycle 2.

The clock B level signal is provided to the selector 15 and the controlled clock signal B of H level is outputted during one cycle period of the cycle 1. The clock A control signal is provided to the AND circuit 13 and the clock signal A is outputted as the controlled clock signal A in the cycle 2. The controlled clock signal A is supplied to the flip-flops of the FF group A 21 and the controlled clock signal B is supplied to the flip-flops of the FF group B 22. In this way, the delay fault test can be performed with the launch clock and the capture clock corresponding to the timing constraint tBA in FIGS. 5B, 5A.

In this case, the controlled clock signal B has the pulse width of the original clock signal B, so that the delay fault test can be reliably performed.

Then, it is assumed that pulse control data configured to generate the launch pulse and the capture pulse corresponding to the timing constraint tBC in FIGS. 5B, 5C is inputted to the pattern conversion table 42. Thus, in this case, BL, CC=1 and AL, CL, AC, BC=0. In this case, when the scan enable input becomes to L level (SE=0), the pulse control data.

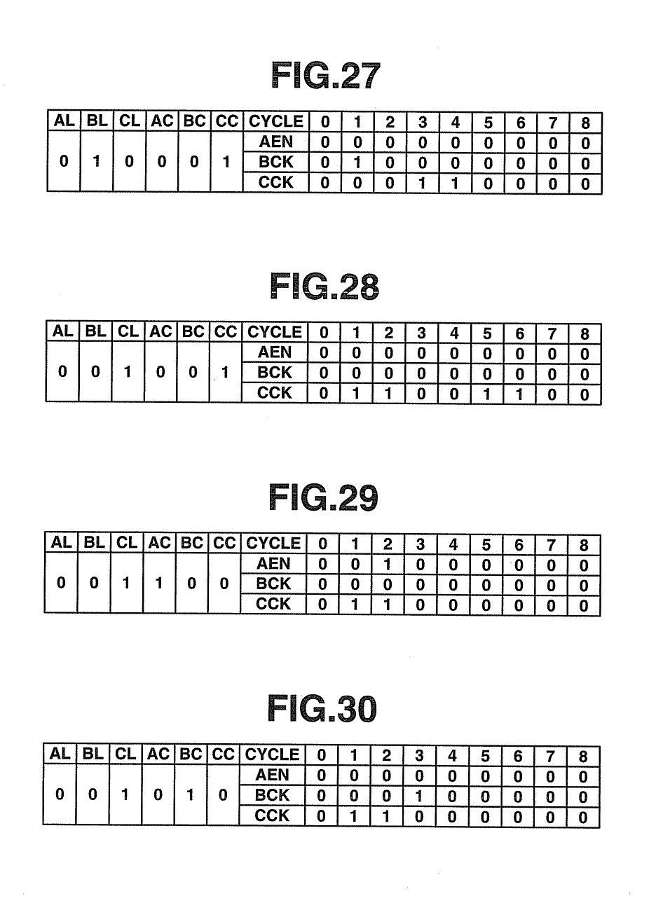

In other words, as shown in FIG. 27, AEN (clock A control signal), BCK (clock B level signal), CCK (clock C level signal) are initialized to 0 in the cycle 0, and 1 is assigned to BCK in the cycle 1. Then, in the cycle 2, BCK is returned to 0 while 1 is assigned to CCK. Further, in the next cycle 3, 1 is continuously assigned to CCK. Thus, in this case, the operation is the same as the timing chart of FIGS. 17A to 17H and the clock B level signal is at H level in the cycle 1 and the clock C level signal is at H level in the cycles 3, 4.

The clock B level signal is provided to the selector 15 and the controlled clock signal B of H level is outputted during one cycle period of the cycle 1. The clock C level signal is provided to the selector 16 and the controlled clock signal C of H level is outputted during two cycle periods of the cycles 3, 4. The controlled clock signal A is supplied to the flip-flops of the FF group A 21 and the controlled clock signal C is supplied to the flip-flops of the FF group C 23. In this way, the delay fault test can be performed with the launch clock and the capture clock corresponding to the timing constraint tBC in FIGS. 5B, 5C.

In this case, the controlled clock signal B has the pulse width of the original clock signal B and the controlled clock signal C has the pulse width of the original clock signal C, so that the delay fault test can be reliably performed.

Then, it is assumed that pulse control data configured to generate the launch pulse and the capture pulse corresponding to the timing constraint tCC in FIG. 4C is inputted to the pattern conversion table 42. Thus, in this case, CL, CC=1 and AL, BL, AC, BC=0. In this case, when the scan enable input becomes to L level (SE=0), the pattern conversion table 42 refers to a conversion table in FIG. 28 in accordance with the pulse control data.

In other words, as shown in FIG. 28, AEN (clock A control signal), BCK (clock B level signal), CCK (clock C level signal) are initialized to 0 in the cycle 0, and 1 is assigned to CCK in the cycle 1. Then, 1 is continuously assigned to CCK also in the cycle 2. Further, CCK is returned to 0 in the cycles 3, 4, and thereafter 1 is assigned to CCK in the cycle 5, 6. Thus, in this case, the operation is the same as the timing chart of FIGS. 18A to 18H and the clock C level signal is continuously at H level in the cycles 1, 2 and the clock C level signal is continuously at H level in the cycles 5, 6, also.

The clock C level signal is provided to the selector 16 and the controlled clock signal C of H level is outputted during two cycle periods of the cycles 1, 2 and further the controlled clock signal C of H level is outputted during two cycle periods of the cycles 5, 6. In this way, the delay fault test can be performed with the launch clock and the capture clock corresponding to the timing constraint tCC in FIG. 4C.

In this case, the controlled clock signal C has the pulse width of the original clock signal C, so that the delay fault test can be reliably performed.

Then, it is assumed that pulse control data configured to generate the launch pulse and the capture pulse corresponding to the timing constraint tCA in FIGS. 5C, 5A is inputted to the pattern conversion table 42. Thus, in this case, CL, AC=1 and AL, BL, BC, CC=0. In this case, when the scan enable input becomes to L level (SE=0), the pattern conversion table 42 refers to a conversion table in FIG. 29 in accordance with the pulse control data.

In other words, as shown in FIG. 29, AEN (clock A control signal), BCK (clock B level signal), CCK (clock C level signal) are initialized to 0 in the cycle 0, and 1 is assigned to CCK in the cycle 1. Then, also in the cycle 2, 1 is continuously assigned to CCK while 1 is assigned to AEN. Thus, in this case, the operation is the same as the timing chart of FIGS. 19A to 19H and the clock C level signal is at H level in the cycles 1, 2 and the clock A control signal is also at H level in the cycle 2.

The clock C level signal is provided to the selector 16 and the controlled clock signal C of H level is outputted during two cycle periods of the cycles 1, 2. The clock A control signal is provided to the AND circuit 13 and the clock signal A is outputted as the controlled clock signal A in the cycle 2. The controlled clock signal A is supplied to the flip-flops of the FF group A 21 and the controlled clock signal C is supplied to the flip-flops of the FF group C 23. In this way, the delay fault test can be performed with the launch clock and the capture clock corresponding to the timing constraint tCA in FIGS. 5C, 5A.

In this case, the controlled clock signal C has the pulse width of the original clock signal C, so that the delay fault test can be reliably performed.

Then, it is assumed that pulse control data configured to generate the launch pulse and the capture pulse corresponding to the timing constraint tCB in FIGS. 6C, 6B is inputted to the pattern conversion table 42. Thus, in this case, CL, BC=1 and AL, BL, AC, CC=0. In this case, when the scan enable input becomes to L level (SE=0), the pattern conversion table 42 refers to a conversion table in FIG. 30 in accordance with the pulse control data.

In other words, as shown in FIG. 30, AEN (clock A control signal), BCK (clock B level signal), CCK (clock C level signal) are initialized to 0 in the cycle 0, and 1 is assigned to CCK in the cycle 1. Further, also in the cycle 2, 1 is continuously assigned to CCK. Then, in the cycle 3, CCK is returned to 0 while 1 is assigned to BCK. Thus, in this case, the operation is the same as the timing chart of FIGS. 20A to 20H and the clock C level signal is at H level in the cycles 1, 2 and the clock B level signal is at H level in the cycle 3.

The clock C level signal is provided to the selector 16 and the controlled clock signal C of H level is outputted during two cycle periods of the cycles 1, 2. The clock B level signal is provided to the selector 15 and the controlled clock signal B of H level is outputted during one cycle period of the cycle 3. The controlled clock signal B is supplied to the flip-flops of the FF group B 22 and the controlled clock signal C is supplied to the flip-flops of the FF group C 23. In this way, the delay fault test can be performed with the launch clock and the capture clock corresponding to the timing constraint tCB in FIGS. 6C, 6B.

In this case, the controlled clock signal B has the pulse width of the original clock signal B and the controlled clock signal C has the pulse width of the original clock signal C, so that the delay fault test can be reliably performed.

Thus, this embodiment has the same effect as in the first embodiment.

Although the example in which one capture clock is generated for one launch clock has been described in the above described embodiments, the present invention is also applicable to the case where one or more capture clocks are generated for one or more launch clocks.

Further, although the example of the semiconductor integrated circuit apparatus equipped with a circuit which allows the scan chain and scan test has been described in the above described embodiments, the present invention is also applicable to the semiconductor integrated circuit apparatus which is not provided with the circuit which allows the scan chain and scan test, by providing adequate inputting means configured to set data to the flip-flops of each group.

Furthermore, it is apparent that the present invention is not limited to the above described nine patterns of timing constraints, and launch clocks and capture clocks corresponding to various timing constraints can be generated.

According to the above described embodiments, a semiconductor integrated circuit apparatus for which a fault test can be performed with a test clock having an adequate pulse width, a test circuit of the semiconductor integrated circuit apparatus, and a test method of the semiconductor integrated circuit apparatus can be achieved.

Having described the embodiments of the invention referring to the accompanying drawings, it should be understood that the present invention is not limited to those precise embodiments and various changes and modifications thereof could be made by one skilled in the art without departing from the spirit or scope of the invention as defined in the appended claims.

What is claimed is:

1. A semiconductor integrated circuit apparatus comprising:
a plurality of flip-flops configured to operate with clocks having mutually different frequencies;
an oscillator configured to output oscillation output that is a source of the clocks supplied to the flip-flops;
a storage part configured to store control data for a delay fault test;
a pulse control part configured to use the oscillation output of the oscillator to generate a launch clock and a capture clock used in the delay fault test, based on the control data, the pulse control part generating the launch clock and the capture clock having pulse widths corresponding to periods of the clocks which operate the flip-flops.

2. The semiconductor integrated circuit apparatus according to claim 1, wherein the plurality of flip-flops is writable and readable by a scan test circuit.

3. The semiconductor integrated circuit apparatus according to claim 1, wherein the pulse control part generates the launch clock and the capture clock with a timing based on the smallest timing constraint which is determined in accordance with combination of the clocks specified by the control data.

4. The semiconductor integrated circuit apparatus according to claim 1, wherein the pulse control part includes a state machine whose output level state changes based on the control data for each cycle based on the oscillation output of the oscillator.

5. The semiconductor integrated circuit apparatus according to claim 3, wherein the pulse control part includes a state machine whose output level state changes based on the control data for each cycle based on the oscillation output of the oscillator.

6. The semiconductor integrated circuit apparatus according to claim 1, wherein the pulse control part generates the launch clock and the capture clock by referring to a table which determines output level based on the control data for each cycle based on the oscillation output of the oscillator.

7. The semiconductor integrated circuit apparatus according to claim 3, wherein the pulse control part generates the launch clock and the capture clock by referring to a table which determines output level based on the control data for each cycle based on the oscillation output of the oscillator.

8. An embedded test circuit of a semiconductor integrated circuit apparatus, the embedded test circuit being integrated, together with a plurality of flip-flops configured to operate with clocks having mutually different frequencies, on the same semiconductor chip to perform a delay fault test of the flip-flops, comprising;
an oscillator configured to output oscillation output that is a source of the clocks supplied to the flip-flops;
a storage part configured to store control data for the delay fault test;
a pulse control part configured to use the oscillation output of the oscillator to generate a launch clock and a capture clock used in the delay fault test, based on the control data, the pulse control part generating the launch clock and the capture clock having pulse widths corresponding to periods of the clocks which operate the flip-flops.

9. The test circuit of a semiconductor integrated circuit apparatus according to claim 8, wherein the plurality of flip-flops is writable and readable by a scan test circuit.

10. The test circuit of a semiconductor integrated circuit apparatus according to claim 8, wherein the pulse control part generates the launch clock and the capture clock with a timing based on the smallest timing constraint which is determined in accordance with combination of the clocks specified by the control data.

11. The test circuit of a semiconductor integrated circuit apparatus according to claim 8, wherein the pulse control part includes a state machine whose output level state changes based on the control data for each cycle based on the oscillation output of the oscillator.

12. The test circuit of a semiconductor integrated circuit apparatus according to claim 10, wherein the pulse control part includes a state machine whose output level state changes based on the control data for each cycle based on the oscillation output of the oscillator.

13. The test circuit of a semiconductor integrated circuit apparatus according to claim 8, wherein the pulse control part generates the launch clock and the capture clock by referring to a table which determines output level based on the control data for each cycle based on the oscillation output of the oscillator.

14. The test circuit of a semiconductor integrated circuit apparatus according to claim 10, wherein the pulse control part generates the launch clock and the capture clock by referring to a table which determines output level based on the control data for each cycle based on the oscillation output of the oscillator.

15. A test method of a semiconductor integrated circuit apparatus, comprising:
outputting oscillation output that is a source of clocks supplied to a plurality of flip-flops configured to operate with clocks having mutually different frequencies, from an oscillator, and
generating a launch clock and a capture clock used in a delay fault test, with pulse widths corresponding to periods of the clocks which operate the flip-flops, by using the oscillation output of the oscillator and control data for the delay fault test stored in a storage part.

16. The test method of a semiconductor integrated circuit apparatus according to claim 15, wherein the plurality of flip-flops is writable and readable by a scan test circuit.

17. The test method of a semiconductor integrated circuit apparatus according to claim 15, comprising;
generating the launch clock and the capture clock with a timing based on the smallest timing constraint which is determined in accordance with combination of clocks specified by the control data.

18. The test method of a semiconductor integrated circuit apparatus according to claim 15, comprising;
generating the launch clock and the capture clock by a state machine whose output level state changes based on the control data for each cycle based on the oscillation output of the oscillator.

19. The test method of a semiconductor integrated circuit apparatus according to claim 17, comprising;
generating the launch clock and the capture clock by a state machine whose output level state changes based on the control data for each cycle based on the oscillation output of the oscillator.

20. The test method of a semiconductor integrated circuit apparatus according to claim 15, comprising;
generating the launch clock and the capture clock by referring to a table which determines output level based on the control data for each cycle based on the oscillation output of the oscillator.
